(19) United States
(12) Patent Application Publication
(10) Pub. No.: US 2012/0001203 A1
(43) Pub. Date: Jan. 5, 2012

(54) LED CHIP PACKAGE STRUCTURE

(75) Inventors: BILY WANG, HSINCHU CITY (TW); JONNIE CHUANG, NEW TAIPEI CITY (TW); WEN-KUEI WU, HSINCHU COUNTY (TW)

(73) Assignee: HARVATEK CORPORATION, HSIN CHU CITY (TW)

(21) Appl. No.: 13/235,585

(22) Filed: Sep. 19, 2011

Related U.S. Application Data
(63) Continuation-in-part of application No. 11/483,619, filed on Jul. 11, 2006.

(51) Int. Cl. H01L 27/15; H01L 33/50

(52) U.S. Cl. 257/88; 257/E33.061; 257/E27.121

(57) ABSTRACT

A LED chip package structure includes a substrate unit, a light-emitting unit, and a package unit. The substrate unit includes a strip substrate body. The light-emitting unit includes a plurality of LED chips disposed on the strip substrate body and electrically connected to the strip substrate body. The package unit includes a strip package colloid body disposed on the strip substrate body to cover the LED chips, wherein the strip package colloid body has an exposed top surface and an exposed surrounding peripheral surface connected between the exposed top surface and the strip substrate body, and the strip package colloid body has at least one exposed lens portion projected upwardly from the exposed top surface thereof and corresponding to the LED chips. Hence, light beams generated by the LED chips pass through the strip package colloid body to form a strip light-emitting area on the strip package colloid body.

### CROSS REFERENCE TO RELATED APPLICATION

This application is a continuation-in-part of U.S. application Ser. No. 11/483,619, filed on 11 Jul. 2006 and entitled “LED chip package structure and method for manufacturing the same”, currently pending.

### BACKGROUND OF THE INVENTION

1. Field of the Invention

The instant disclosure relates to a LED chip package structure, and particularly relates to a LED chip package structure for generating a strip light-emitting area on the LED chip package structure.

2. Description of Related Art

Referring to FIGS. 1A to 1C, a known LED package structure is manufactured via a wire-bounding process. The known LED package structure includes a substrate 1a, a plurality of LEDs 2a disposed on the substrate 1a, a plurality of wires 3a, and a plurality of fluorescent colloids 4a.

Each of the LEDs 2a is disposed on the substrate 1a, and each LED 2a has positive and negative electrode areas 21a, 22a respectively electrically connected with a corresponding positive area 11a and a corresponding negative electrode area 12a of the substrate 1a. Moreover, each fluorescent colloid 4a is correspondingly covered over each LED 2a and two wires 3a for protecting the LEDs 2a.

However, because each fluorescent colloid 4a needs to be covered over each corresponding LED 2a, the known package process is time-consuming. Moreover, because the fluorescent colloids 4a are separated from each other, a dark band is easily produced between the two fluorescent colloids 4a or the two LEDs 2a. Hence, the known LED package structure is hard to show a good vision for users.

### SUMMARY OF THE INVENTION

One aspect of the instant disclosure relates to a LED chip package structure. The LED chip package structure includes a plurality of LED chips disposed on a strip substrate body by an adhesive or a hot pressing method for generating light. The substrate unit is a PCB, a flexible substrate, an aluminum substrate, or a ceramic substrate. Each LED chip is electrically connected with the substrate unit via two corresponding wires by a wire-bounding method or via a plurality of solder balls by a flip-chip method. Moreover, a package unit is used to cover the substrate unit and the light-emitting unit for guiding the light from the light-emitting unit to form a series of light-generating areas on the package unit. Hence, because the series of light-generating areas is continuous, there is no any dark band between the LED chips. Furthermore, because the package unit is a continuous colloid body, the process of the LED chip package structure is simple for reducing manufacturing time.

One of the embodiments of the instant disclosure provides a LED chip package structure, comprising: a substrate unit, a light-emitting unit, and a package unit. The substrate unit includes a strip substrate body. The light-emitting unit includes a plurality of LED chips disposed on the strip substrate body and electrically connected to the strip substrate body. The package unit includes a strip package colloid body disposed on the strip substrate body to cover the LED chips, wherein the strip package colloid body has an exposed top surface and an exposed surrounding peripheral surface connected between the exposed top surface and the strip substrate body, and the strip package colloid body has at least one exposed lens portion projected upwardly from the exposed top surface thereof and corresponding to the LED chips. Hence, light beams generated by the LED chips pass through the strip package colloid body to form a strip light-emitting area on the strip package colloid body.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1A shows a perspective view of the LED package structure according to the prior art;

FIG. 1B shows a front view of the LED package structure according to the prior art;

FIG. 1C shows a top view of the LED package structure according to the prior art;

FIG. 2A shows a perspective view of the LED chip package structure according to the first embodiment of the instant disclosure;

FIG. 2B shows a top view of the LED chip package structure according to the first embodiment of the instant disclosure;

FIG. 2C shows a top view of a larger and parallel-type LED chip package structure according to the second embodiment of the instant disclosure;

FIG. 2D shows a top view of an reassembled LED chip package structure from the second embodiment of the instant disclosure;

FIG. 3A shows a perspective view of the LED chip package structure according to the third embodiment of the instant disclosure;

FIG. 3B shows a top view of the LED chip package structure according to the third embodiment of the instant disclosure;

FIG. 3C shows a top view of a larger and serial-type LED chip package structure according to the fourth embodiment of the instant disclosure;

FIG. 3D shows a top view of an reassembled LED chip package structure from the fourth embodiment of the instant disclosure;

FIG. 4A shows a perspective view of the LED chip package structure according to the fifth embodiment of the instant disclosure;

FIG. 4B shows a top view of the LED chip package structure according to the fifth embodiment of the instant disclosure;

FIG. 4C shows a top view of a larger and serial-type LED chip package structure according to the sixth embodiment of the instant disclosure;

FIG. 4D shows a top view of an reassembled LED chip package structure from the sixth embodiment of the instant disclosure;

FIG. 5A shows a perspective, schematic view of the LED chip package structure according to the seventh embodiment of the instant disclosure;

FIG. 5B shows a top, schematic view of the LED chip package structure according to the seventh embodiment of the instant disclosure; and

FIG. 5C shows a lateral, cross-sectional, schematic view of the LED chip package structure according to the seventh embodiment of the instant disclosure.

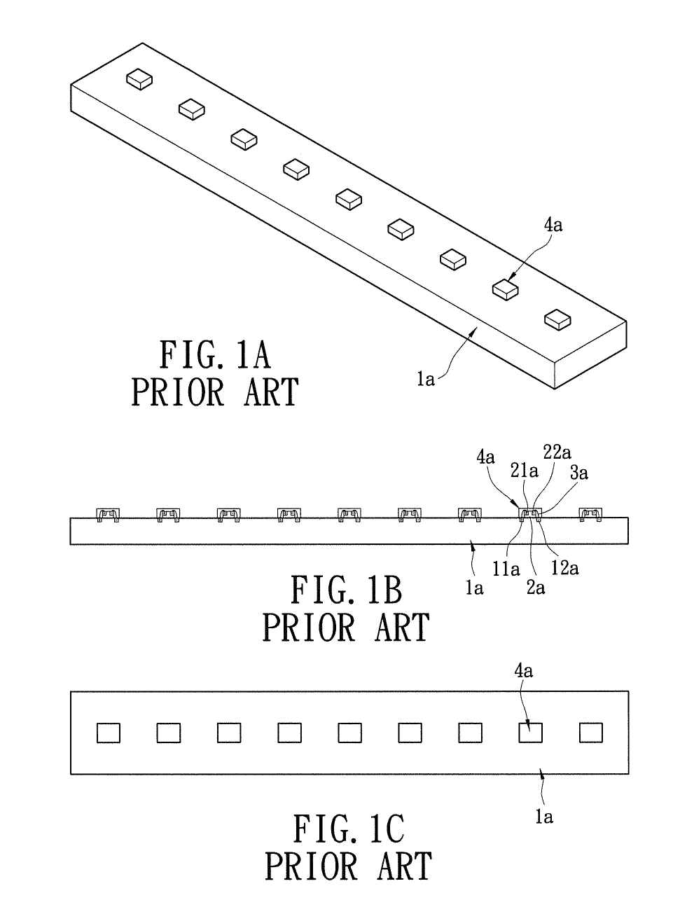

### DETAILED DESCRIPTION OF THE PREFERRED EMBODIMENTS

### First Embodiment

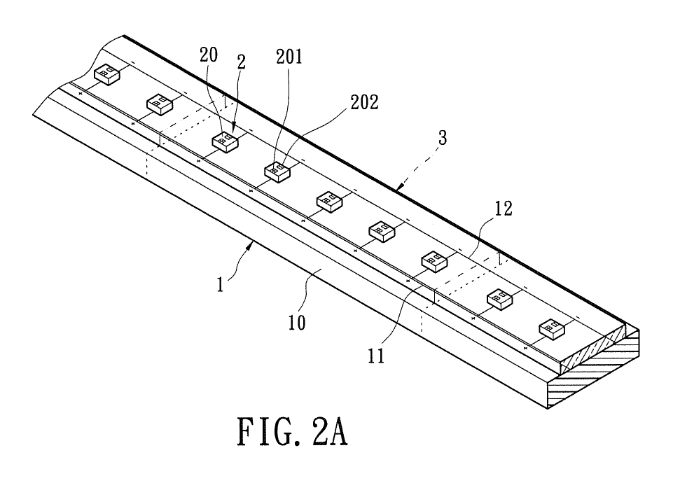

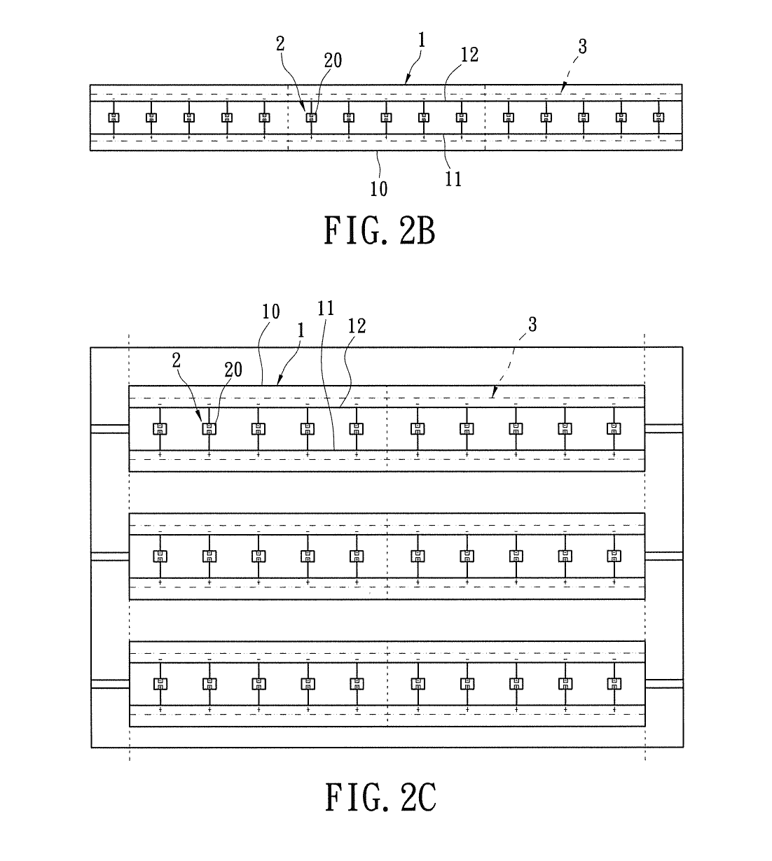

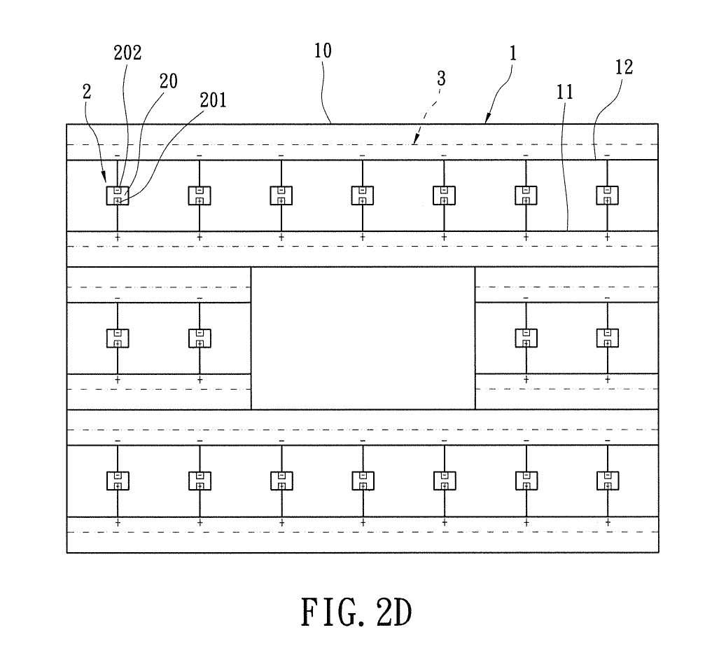

Referring to FIGS. 2A and 2B, the first embodiment of the instant disclosure provides a LED chip package structure, comprising a substrate unit 1, a light-emitting unit 2, and a package unit 3.

The substrate unit has a strip substrate body 10, and a positive electrode trace 11 and a negative electrode trace 12 respectively formed on the strip substrate body 10 by an etching, a printing or any other forming methods. The light-emitting unit 2 has a plurality of LED chips 20 disposed on the strip substrate body in a straight line by an adhesive or a hot pressing method for generating light. Moreover, each of the LED chips 20 has a positive side 201 and a negative side 202 parallel electrically connected with the positive electrode trace 11 and the negative electrode trace 12 via corresponding wires, respectively. Furthermore, the positive side 201 and the negative side 202 can also parallel electrically connected with the positive electrode trace 11 and the negative electrode trace 12 via corresponding solder balls (not shown), respectively. In addition, the solder balls are disposed on the substrate unit 1 by a hot-pressing method.

Furthermore, the package unit 3 is used to cover the substrate unit 1 and the light-emitting unit 2 for guiding the light from the light-emitting unit 2 to form a series of light-generating areas on the package unit 3. The package unit 3 can also prevent the light-emitting unit 2 from being damaged.

### Second Embodiment

Referring to FIG. 2C, the second embodiment of the instant disclosure provides a larger and parallel-type LED chip package structure that comprises a plurality of light-emitting units 2 respectively disposed on a corresponding substrate unit 1 in a plurality of straight lines via the parallel method of the first embodiment. Moreover, the larger LED chip package structure can be cut into a plurality of slender LED package structures, and the slender LED package structures can be arranged into any shape such as a hollow square as shown in FIG. 2D.

### Third Embodiment

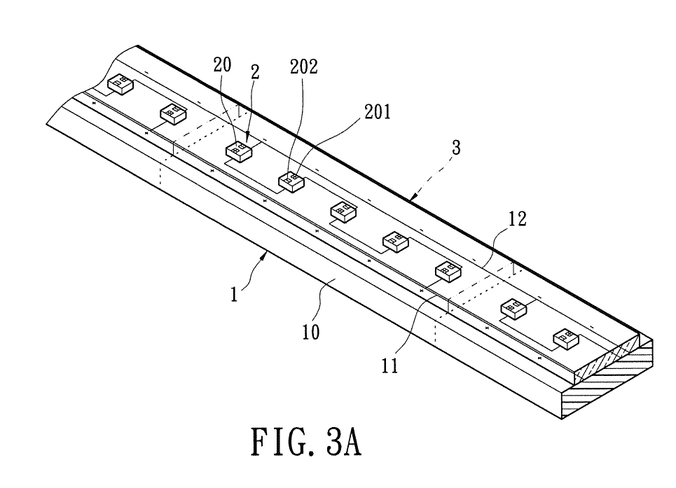

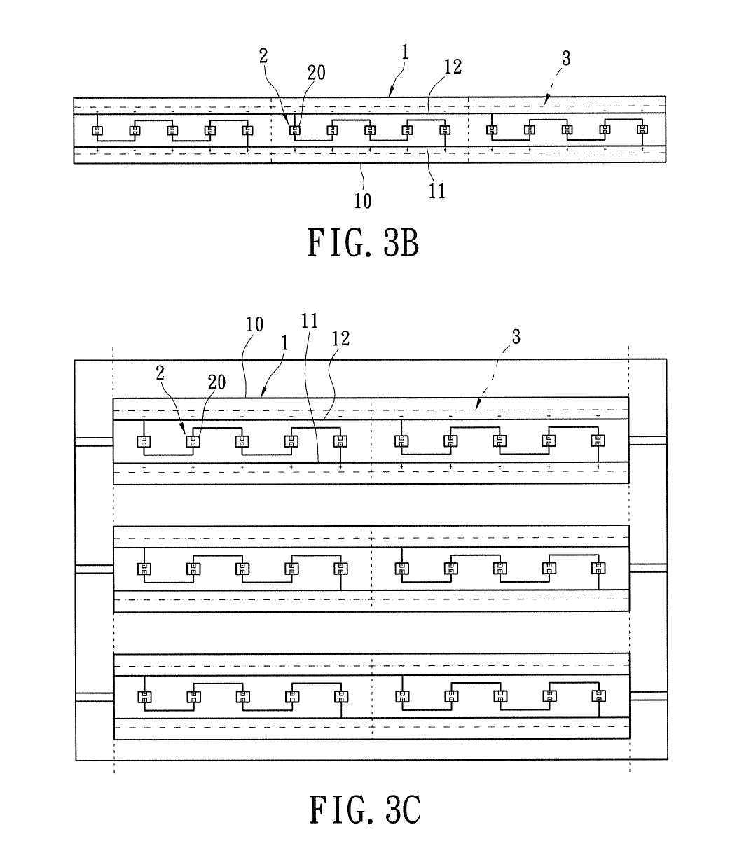

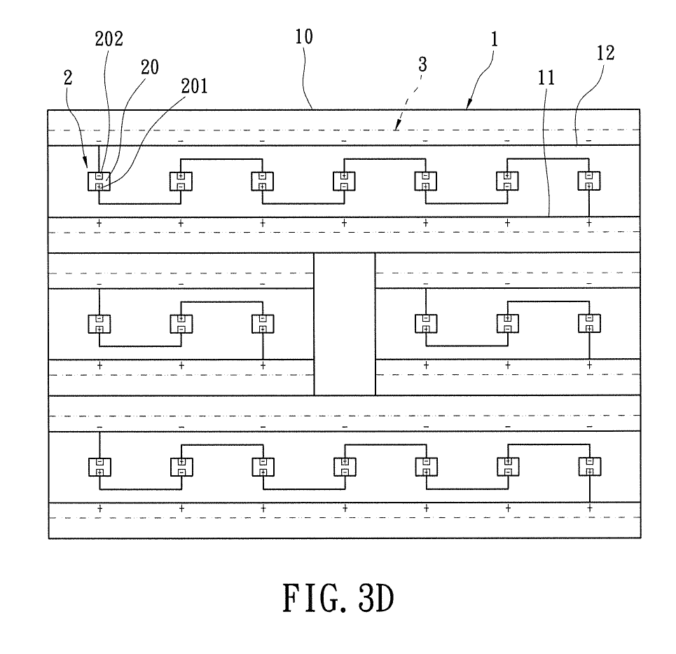

Referring to FIGS. 3A and 3B, the difference between the third embodiment and the first embodiment is as follows: in the third embodiment, an arrangement direction of the positive electrode side 201 of each LED chip 20 is opposite to that of an adjacent LED chip. Moreover, the positive side 201 and the negative side 202 of each of the LED chips 20 are serially electrically connected with the positive electrode trace 11 and the negative electrode trace 12 via corresponding wires, respectively. The above serial shape appears to be U-shaped between every two LED chips 20.

### Fourth Embodiment

Referring to FIG. 3C, the fourth embodiment of the instant disclosure provides a larger and serial-type LED chip package structure that comprises a plurality of light-emitting units 2 respectively disposed on a corresponding substrate unit 1 via the serial method of the third embodiment. Moreover, the larger LED chip package structure can be cut into a plurality of slender LED package structures, and the slender LED package structures can be arranged into any shape such as a hollow square as shown in FIG. 3D.

### Fifth Embodiment

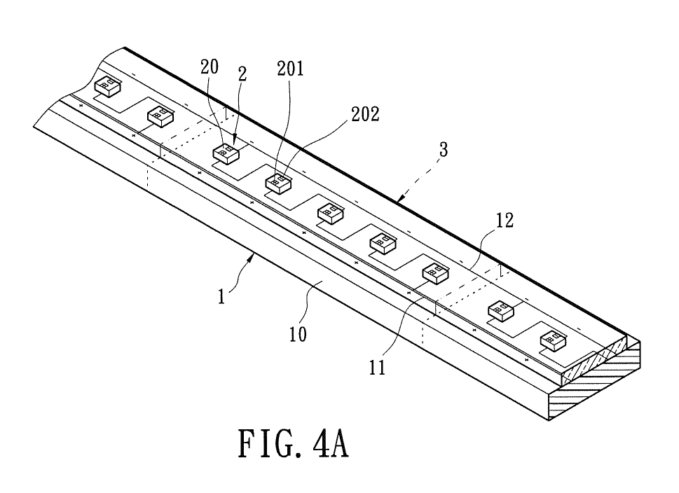

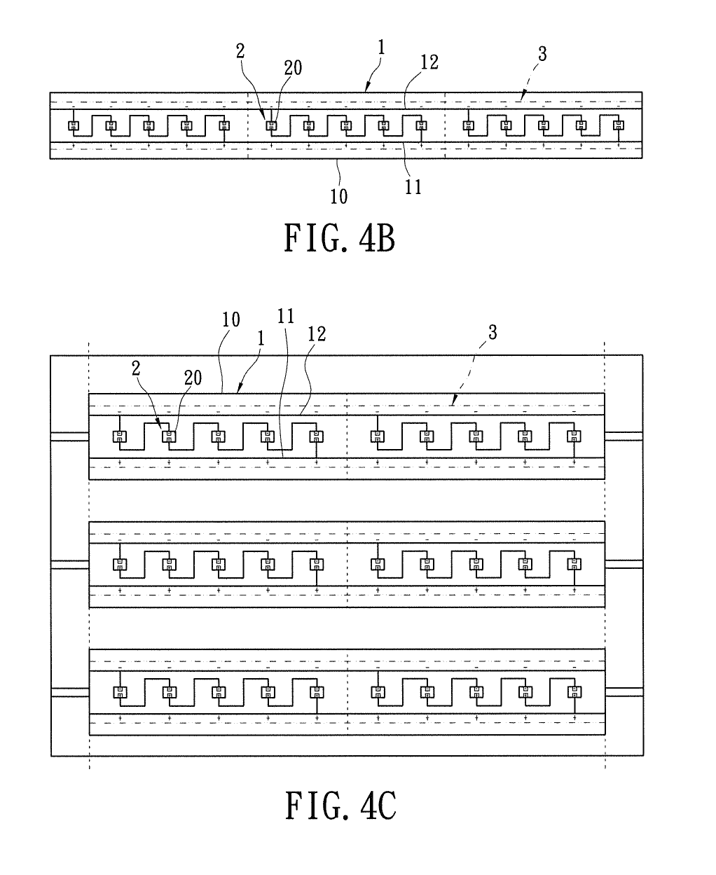

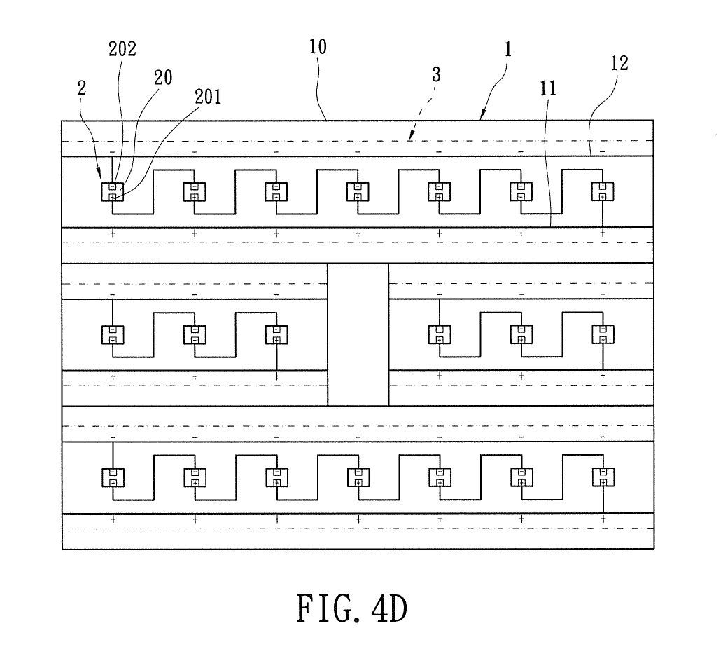

Referring to FIGS. 4A and 4B, the difference between the fifth embodiment and the third embodiment is as follows: in the fifth embodiment, an arrangement direction of the positive electrode side 201 of each LED chip 20 is the same as that of an adjacent LED chip. Moreover, the positive side 201 and the negative side 202 of each of the LED chips 20 are serially electrically connected with the positive electrode trace 11 and the negative electrode trace 12 via corresponding wires, respectively. The above serial shape appears to be S-shaped between every two LED chips 20.

### Sixth Embodiment

Referring to FIG. 4C, the sixth embodiment of the instant disclosure provides a larger and serial-type LED chip package structure that comprises a plurality of light-emitting units 2 respectively disposed on a corresponding substrate unit 1 via the serial method of the third embodiment. Moreover, the larger LED chip package structure can be cut into a plurality of slender LED package structures, and the slender LED package structures can be arranged into any shape such as a hollow square as shown in FIG. 4D.

### Seventh Embodiment

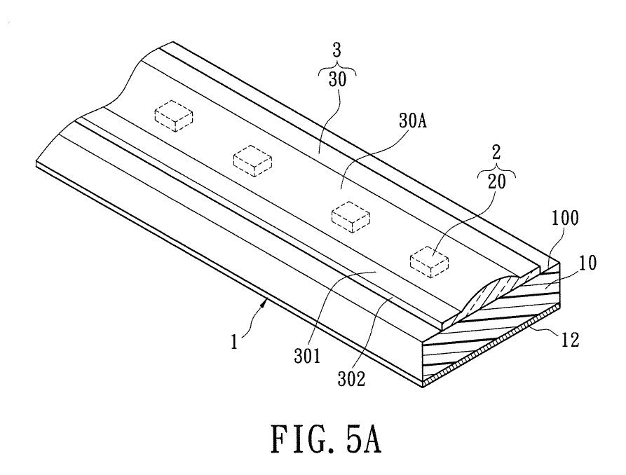

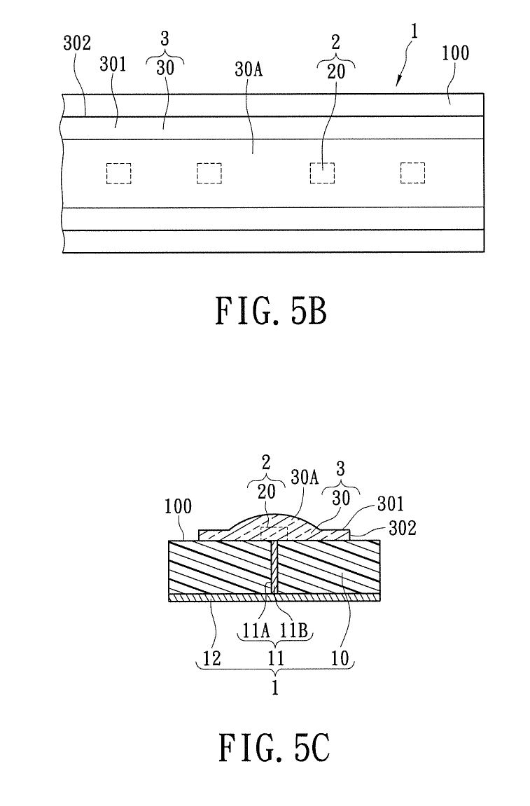

Referring to FIGS. 5A to 5C, the seventh embodiment of the instant disclosure provides a LED chip package structure, comprising: a substrate unit 1, a light-emitting unit 2, and a package unit 3.

The substrate unit 1 includes a strip substrate body 10, a plurality of heat-dissipating structures 11 passing through the strip substrate body 10, and a heat-dissipating layer 12 disposed on the bottom surface of the substrate body 10 to contact the heat-dissipating structures 11. For example, the strip substrate body 10 has a plane top surface 100. Each heat-dissipating structure 11 has at least one heat-dissipating hole 11A passing through the strip substrate body 10 and at least one heat-dissipating body 11B, and the at least one heat-dissipating hole 11A is filled with the at least one heat-dissipating body 11B. The heat-dissipating body 11B may be any type of paste including metal heat-dissipating molecules, such as silver paste, copper paste, etc.

The light-emitting unit 20 includes a plurality of LED chips 20 disposed on the strip substrate body 10 and electrically connected to the strip substrate body 10. For example, the heat-dissipating structures 11 can be respectively disposed under the LED chips 20 to respectively contact the LED chips 20, thus heat generated by the LED chips 20 can be transmitted to the heat-dissipating layer 12 through the heat-dissipating structures 11.

The package unit 3 includes a strip package colloid body 30 disposed on the strip substrate body 10 to cover the LED chips 20. In addition, the strip package colloid body 30 has an exposed top surface 301 and an exposed surrounding peripheral surface 302 connected between the exposed top surface 301 and the strip substrate body 10, and the strip package colloid body 30 has at least one exposed lens portion 30A projected upwardly from the exposed top surface 301 thereof and corresponding to the LED chips 20. In addition, only the bottom surface of the strip package colloid body 30 is hidden by the strip substrate body 10 and the other surfaces (such as light-output surfaces) of the strip package colloid body 30 are completely exposed, thus light beams (not shown) generated by the LED chips 20 can be guided to go away from the light-output surfaces (the other surfaces) of the strip package colloid body 30 without using any reflection frame that has been formed on the strip substrate body 10.

For example, the exposed top surface 301 of the strip package colloid body 30 can be substantially horizontal to the plane top surface 100 of the strip substrate body 10, and the exposed surrounding peripheral surface 302 of the strip package colloid body 30 can be substantially vertical to the plane top surface 100 of the strip substrate body 10. The strip package colloid body 30 can be formed by mixing a plurality of phosphor powders with one of silicone and epoxy. The exposed lens portion 30A can be integrally formed on the exposed top surface 301 of the strip package colloid body 30 and disposed above the LED chips 20. Hence, light beams (not shown) generated by the LED chips 20 can pass through the strip package colloid body 30 to form a strip light-emitting area on the strip package colloid body 30.

Of course, the seventh embodiment can omit the exposed lens portion 30A, thus the whole exposed top surface 301 of the strip package colloid body 30 is plane and is substantially horizontal to the plane top surface 100 of the strip substrate body 10 and substantially vertical to the exposed surrounding peripheral surface 302 of the strip package colloid body 30. Furthermore, the exposed surrounding peripheral surface 302 of the strip package colloid body 30 can separated from the lateral surface of the strip substrate body 10 or can be substantially flushed with the lateral surface of the strip substrate body 10. In addition, the exposed lens portion 30A also can be divided into a plurality of exposed lens units respectively corresponding to the LED chips 20 and respectively disposed above the LED chips 20.

In conclusion, the LED chips 20 are disposed on the strip substrate body 10 by the adhesive or the hot pressing method for generating light. Moreover, the package unit 3 is used to cover the substrate unit 1 and the light-emitting unit 2 for guiding the light from the light-emitting unit to form the series of light-generating areas on the package unit 3. Hence, because the series of light-generating areas is continuous, there is no any dark band between every two LED chips 20. Furthermore, because the package unit 3 is a continuous colloid body, the process of the LED chip package structure is simple for reducing manufacturing time.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A LED chip package structure, comprising:
a substrate unit including a strip substrate body;
a light-emitting unit including a plurality of LED chips disposed on the strip substrate body and electrically connected to the strip substrate body; and
a package unit including a strip package colloid body disposed on the strip substrate body to cover the LED chips, wherein the strip package colloid body has an exposed top surface and an exposed surrounding peripheral surface connected between the exposed top surface and the strip substrate body, and the strip package colloid body has at least one exposed lens portion projected upwardly from the exposed top surface thereof and corresponding to the LED chips;
wherein light beams generated by the LED chips pass through the strip package colloid body to form a strip light-emitting area on the strip package colloid body.

2. The LED chip package structure of claim 1, wherein the strip substrate body has a plane top surface, the exposed top surface of the strip package colloid body is substantially horizontal to the plane top surface, and the exposed surrounding peripheral surface of the strip package colloid body is substantially vertical to the plane top surface.

3. The LED chip package structure of claim 1, wherein the substrate unit includes a plurality of heat-dissipating structures passing through the strip substrate body and respectively disposed under the LED chips to respectively contact the LED chips.

4. The LED chip package structure of claim 3, wherein each heat-dissipating structure has at least one heat-dissipating hole passing through the strip substrate body and at least one heat-dissipating body, and the at least one heat-dissipating hole is filled with the at least one heat-dissipating body.

5. The LED chip package structure of claim 3, wherein the substrate unit includes a heat-dissipating layer disposed on the bottom surface of the substrate body to contact the heat-dissipating structures.

6. The LED chip package structure of claim 1, wherein the strip package colloid body is formed by mixing a plurality of phosphor powders with one of silicone and epoxy.

7. The LED chip package structure of claim 1, wherein the exposed lens portion is integrally formed on the exposed top surface of the strip package colloid body and disposed above the LED chips.

8. A LED chip package structure, comprising:
a substrate unit including a strip substrate body and a plurality of heat-dissipating structures passing through the strip substrate body;
a light-emitting unit including a plurality of LED chips disposed on the strip substrate body and electrically connected to the strip substrate body, wherein the heat-dissipating structure are respectively disposed under the LED chips to respectively contact the LED chips; and
a package unit including a strip package colloid body disposed on the strip substrate body to cover the LED chips, wherein the strip package colloid body has an exposed top surface and an exposed surrounding peripheral surface connected between the exposed top surface and the strip substrate body;
wherein light beams generated by the LED chips pass through the strip package colloid body to form a strip light-emitting area on the strip package colloid body.

9. The LED chip package structure of claim 8, wherein the strip substrate body has a plane top surface, the exposed top surface of the strip package colloid body is substantially horizontal to the plane top surface, and the exposed surrounding peripheral surface of the strip package colloid body is substantially vertical to the plane top surface.

10. The LED chip package structure of claim 8, wherein each heat-dissipating structure has at least one heat-dissipating hole passing through the strip substrate body and at least one heat-dissipating body, and the at least one heat-dissipating hole is filled with the at least one heat-dissipating body.

11. The LED chip package structure of claim 8, wherein the substrate unit includes a heat-dissipating layer disposed on the bottom surface of the substrate body to contact the heat-dissipating structures.

12. The LED chip package structure of claim 8, wherein the strip package colloid body is formed by mixing a plurality of phosphor powders with one of silicone and epoxy.

13. The LED chip package structure of claim 8, wherein the strip package colloid body has at least one exposed lens portion projected upwardly from the exposed top surface thereof and corresponding to the LED chips

14. The LED chip package structure of claim 13, wherein the exposed lens portion is integrally formed on the exposed top surface of the strip package colloid body and disposed above the LED chips.

15. A LED chip package structure, comprising:
a substrate unit including a strip substrate body and a plurality of heat-dissipating structures passing through the strip substrate body;
a light-emitting unit including a plurality of LED chips disposed on the strip substrate body and electrically connected to the strip substrate body, wherein the heat-dissipating structure are respectively disposed under the LED chips to respectively contact the LED chips; and
a package unit including a strip package colloid body disposed on the strip substrate body to cover the LED chips, wherein the strip package colloid body has an exposed top surface and an exposed surrounding peripheral surface connected between the exposed top surface and the strip substrate body, and the strip package colloid body has at least one exposed lens portion projected upwardly from the exposed top surface thereof and corresponding to the LED chips;
wherein light beams generated by the LED chips pass through the strip package colloid body to form a strip light-emitting area on the strip package colloid body.

16. The LED chip package structure of claim 15, wherein the strip substrate body has a plane top surface, the exposed top surface of the strip package colloid body is substantially horizontal to the plane top surface, and the exposed surrounding peripheral surface of the strip package colloid body is substantially vertical to the plane top surface.

17. The LED chip package structure of claim 15, wherein each heat-dissipating structure has at least one heat-dissipating hole passing through the strip substrate body and at least one heat-dissipating body, and the at least one heat-dissipating hole is filled with the at least one heat-dissipating body.

18. The LED chip package structure of claim 15, wherein the substrate unit includes a heat-dissipating layer disposed on the bottom surface of the substrate body to contact the heat-dissipating structures.

19. The LED chip package structure of claim 15, wherein the strip package colloid body is formed by mixing a plurality of phosphor powders with one of silicone and epoxy.

20. The LED chip package structure of claim 15, wherein the exposed lens portion is integrally formed on the exposed top surface of the strip package colloid body and disposed above the LED chips.
